(19) United States
(12) Patent Application Publication
(10) Pub. No.: US 2025/0259926 A1
(43) Pub. Date: Aug. 14, 2025

(54) HYBRID BOND FEATURES IN PROGRAMMABLE CIRCUITS

(71) Applicant: International Business Machines Corporation, Armonk, NY (US)

(72) Inventors: Nicholas Alexander POLOMOFF, Hopewell Junction, NY (US); Mukta Ghate Farooq, HOPEWELL JCT, NY (US)

(21) Appl. No.: 18/440,926

(22) Filed: Feb. 13, 2024

(51) Int. Cl. H01L 23/525; H01L 23/00

(52) U.S. Cl. CPC H01L 23/5256; H01L 24/08; H01L 2224/08145

(57) ABSTRACT

An exemplary hybrid bonded semiconductor structure includes a lower semiconductor build, an upper semiconductor build on the lower semiconductor build, a joining interface where the lower and upper semiconductor builds meet, a first e-fuse terminal at least partially in the lower semiconductor build, a second e-fuse terminal at least partially in the upper semiconductor build, and an e-fuse link between the first and second e-fuse terminals wherein the e-fuse link comprises a lower portion in the lower semiconductor build and an upper portion in the upper semiconductor build and the e-fuse link extends across the joining interface.

### BACKGROUND

The present invention relates generally to the electrical, electronic and computer arts and, more particularly, to fuse structures in semiconductor builds and the like.

Historically, fuses allowed for reprogramming of an electronic circuit. In semiconductors, fuses were historically blown by a laser causing physical rupture of the fuse element. With laser blow, adjacent devices may be damaged and could only be done at particular points of the process with special equipment. In contrast, an e-fuse (electronic fuse) is a smaller microscopic fuse put into a computer chip.

Such e-fuses are usually integrated into semiconductor ICs by using a narrow strip commonly called a “fuse link” of conducting material (e.g., polysilicon, silicide, metal, etc.) between two pads, generally referred to as anode and cathode. Applying a programing current to the e-fuse destroys (“blows”) the link, thus changing the resistivity of the e-fuse. This is referred to as “programming” the e-fuse. The fuse state (i.e., whether it has been programmed) can be read using a sensing circuit. Historically, e-fuse materials were made from the polysilicon gate layer. However, with the advent of replacement metal gates, metal e-fuses were introduced in the back end of line (BEOL) (e.g. a fuse element made from a via that connects metal 2 to metal 3). A metal electrically programmable fuse formed in BEOL interconnect structures of a chip requires much less device area than a metal-silicide-based electrically programmable fuse.

In hybrid bonding, a permanent bond combines two semiconductor builds, each having a dielectric and embedded metal (e.g., Cu) on the surface. Two semiconductor builds are joined (e.g., two individual wafers that are built separately). The individual hybrid bonding joining interfaces require “pristine” surface conditions (smooth and flat, possibly with some recesses), more so than traditional BEOL dielectric layers utilizing standard chemical-mechanical planarization (CMP) processing. The surfaces of the two semiconductor builds are purposely designed to align. The term “hybrid” refers to the presence of both metal to metal and dielectric to dielectric bonding. The two semiconductor builds are brought together, and a small heat treatment/annealing process is carried out. The oxides bond together and the metals “anneal,” or almost melt, together, thus fusing the interface into a single bonded part (in some instances, seamlessly; i.e., the interface line disappears).

### BRIEF SUMMARY

Principles of the invention provide e-fuse structures applied to hybrid bonded semiconductor builds.

In one aspect, an exemplary hybrid bonded semiconductor structure includes a lower semiconductor build, an upper semiconductor build on the lower semiconductor build, a joining interface where the lower and upper semiconductor builds meet, a first e-fuse terminal at least partially in the lower semiconductor build, a second e-fuse terminal at least partially in the upper semiconductor build, and an e-fuse link between the first and second e-fuse terminals wherein the e-fuse link comprises a lower portion in the lower semiconductor build and an upper portion in the upper semiconductor build and the e-fuse link extends across the joining interface.

In another aspect, another exemplary hybrid bonded semiconductor structure includes a lower semiconductor build, an upper semiconductor build on the lower semiconductor build, a joining interface where the lower and upper semiconductor builds meet, a first e-fuse terminal in the first semiconductor build, a second e-fuse terminal comprising an upper contact pad in the upper semiconductor build in contact with a lower contact pad in the lower semiconductor build, and an e-fuse link between the first and second e-fuse terminals.

In a further aspect, an exemplary hybrid bonded semiconductor structure includes a lower semiconductor build, an upper semiconductor build on the lower semiconductor build, a joining interface where the lower and upper semiconductor builds meet, a first e-fuse terminal in the first semiconductor build, a second e-fuse terminal comprising an upper contact pad in the upper semiconductor build in contact with a lower contact pad in the lower semiconductor build, and an e-fuse link between the first and second e-fuse terminals wherein the top surface of the first terminal is at least partially covered by the e-fuse link.

In a further aspect, an exemplary hybrid bonded semiconductor structure includes a lower semiconductor build, an upper semiconductor build on the lower semiconductor build, a joining interface where the lower and upper semiconductor builds meet, a first e-fuse terminal, a second e-fuse terminal, wherein each e-fuse terminal comprises an upper contact pad in the upper semiconductor build in contact with a lower contact pad in the lower semiconductor build, and an e-fuse link connecting the first and second e-fuse terminals.

In a further aspect, an exemplary hybrid bonded semiconductor structure includes a lower semiconductor build, an upper semiconductor build on the lower semiconductor build, a joining interface where the lower and upper semiconductor builds meet, an upper contact pad in the upper semiconductor build in contact with a lower contact pad in the lower semiconductor build, a vertical e-fuse link at a via level electrically connected to the lower contact pad, and a heater adjacent the vertical e-fuse link.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. Generally, the e-fuse embodiments allow controlling access signals between two builds which, by way of example only and without limitation, one or more embodiments may provide one or more of:
Allow improved yield at wafer, module and final assembly test levels due to simpler build or redundancy. Due to these structures being built in the later stages of each respective semiconductor build, the e-fuse hybrid structure is less disruptive to the process flow when compared to their traditional counterparts. Specifically, there are fewer special or additional process steps that are needed to build them. They are therefore easier to make then their traditional counterparts and are less likely to cause issues with the build and overall more good chips produced. The e-fuses when used in combination with redundant chips a semiconductor assembly can be used to implement back up die or chips. For example, if a build having multiple die adjoined together has a particular die to die connection that is compromised or not functioning properly, this misfunction could be detected and result in triggering of e-fuses connecting a different back up die to turn on thus improving the yield of the package assembly. This is special because yield improvement for packaged assemblies is elusive/difficult to mitigate because if a bad chip is joined to a good chip, the packaged assembly is no good.
Allow flexibility in logic function and system use. Inter-chip performance tuning between the adjoined semiconductor builds can be achieved. For example, if certain sub-systems fail, are taking too long to respond, or are consuming too much power, the structure can instantly change its behavior by blowing an e-fuse. Additionally, as it relates to flexibility, integrated circuit (“IC”) designers can use e-fuses to customize the behavior or features of a memory device based on user preferences or specific application requirements. This provides a flexible way to tailor memory configurations. Additionally, the e-fuses could be used as part of error correction mechanisms. The altered state of an e-fuse can be interpreted to correct errors or indicate specific conditions in the memory system.Mitigate electrical damage (e.g. over-current, electromigration, etc.) that could occur due to the joining interface boundary of semiconductor builds. E-fuse can provide circuit protection. They can be leveraged as protective elements that limit circuit currents, voltages to safe levels during fault conditions. If voltage or current is too high or a power surge accidently occurs, they can be prevent such a voltage/current from reaching and damaging sensitive circuitry, devices, memory elements, etc. an e-fuse can provide overcurrent, overvoltage, overtemperature, and reverse polarity protection for electronic devices and across the adjoined semiconductor builds. They can be programmed to blow when the current exceeds a certain limit, thus protecting the device from damage.
Relating to the above regarding electrical surge protection. The e-fuses could be used as a components that exhibit resistance to flow of the electrical currents controlling the amount of current going into and out of a circuit which is key to regulating voltage levels and protecting the electronic devices and components of the build. The e-fuses can also be designed and leveraged in a way to alter the resistance of a circuit design—where a different number of fuses, etc. can be blown to change the circuits overall resistance for some desired purpose.
Allows security functions. The e-fuses across the two adjoined semiconductor builds could be configured leverage as security features that limit the electrical signal access from one build to another. The e-fuses could be part of a security-based circuit that will only activate with the correct voltage to blow said fuses upon the input or application of a correct password, etc. Sensitive information or data could be protected on one of the adjoined semiconductor builds behind an e-fuse that must be activated of triggered or visa versa to access or block access to this data. For instance, an integrated circuit manufacturer might use e-fuses to set specific parameters or unique identifiers like lot numbers. Additionally, e-fuses can be employed to store security-related information, contributing to the secure operation of the device.
Allows restrictive and memory programming applications. Resistive programming in semiconductors refers to a process where the resistance of a material is deliberately altered to store or manipulate data. Here, an e-fuse can be placed that can be activated (blown) to access or block such things as various different non-volatile memory types. E-fuses could also be as storage states themselves where resistance changes from the ‘blown’ e-fuses are used to create different states, allowing the storage of binary information. This technology is employed for non-volatile memory applications. The e-fuses can be employed to store information in a non-volatile manner. When an e-fuse is “blown” or programmed, it undergoes a permanent change in its electrical characteristics. This altered state can represent binary data, commonly “0” or “1,” and it persists even when the power is turned off. Additionally, the e-fuses can be used for One-Time-Programmable (OTP) Memory: e-fuses are often considered a type of OTP memory. Once programmed, the information is typically irreversible, making e-fuses suitable for scenarios where a one-time, permanent configuration is needed. One-Time-Programmable (OTP) memory elements are also used in ICs to provide Non-Volatile Memory (NVM). Data in NVM is not lost when the IC is turned off. NVM allows an IC manufacturer to store a lot number and security data on the IC, for example, and is useful in many other applications. A non-volatile memory, such as a Read-Only Memory (ROM), may include a plurality of memory cells, each of which may include a transistor connected to a word line and a e-fuse or dFuse connected to a bit line. When programming a “1”, the e-fuse or dFuse may be blown by applying write voltages to the word and bit lines (e.g., to breakdown a dielectric comprising, for example, oxide between elements of the dFuse thus blowing the dFuse).
The technology allows for dynamic real-time reprogramming of chips. In general, computer circuits are fixed and cannot be changed after the chip manufacturing. By utilizing a set of e-fuses, a chip manufacturer can allow for the circuits on a chip to change while it is in operation.
Provide in-chip performance tuning. If certain sub-systems fail, or are taking too long to respond, or are consuming too much power, the chip can instantly change its behavior by blowing an e-fuse. E-fuses are used to etch serialization or calibration data onto a chip thus making it a read-only value. E-fuses are also commonly used as a one-time programmable ROM or write-restricted memory, and not actual physical electric fuses. This ranges from writing unique information onto CPUs, or in the case of game consoles and other restricted hardware, preventing downgrades by permanently recording a newer version.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A is a cross-section view of a hybrid bonded semiconductor structure including an e-fuse in accordance with aspects of the invention;

FIG. 1B is a top-down view illustrating various configurations an e-fuse structure may have in accordance with aspects of the invention;

FIG. 2 is a cross-section view of a hybrid bonded semiconductor structure including an e-fuse in accordance with aspects of the invention;

FIG. 3 is a cross-section view of a hybrid bonded semiconductor structure including an e-fuse in accordance with aspects of the invention;

FIG. 4 is a cross-section view of a hybrid bonded semiconductor structure including an e-fuse in accordance with aspects of the invention;

FIG. 5 is a cross-section view of a hybrid bonded semiconductor structure including an e-fuse in accordance with aspects of the invention; and

FIGS. 6A and 6B are top-down views illustrating various configurations a heater structure may have in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

In one aspect, an exemplary hybrid bonded semiconductor structure 100 includes a lower semiconductor build 102, an upper semiconductor build 101 on the lower semiconductor build, a joining interface 130 where the lower and upper semiconductor builds meet, a first e-fuse terminal 141 at least partially in the lower semiconductor build, a second e-fuse terminal 142 at least partially in the upper semiconductor build 101, and an e-fuse link 150 between the first and second e-fuse terminals wherein the e-fuse link 150 comprises a lower portion 105-L in the lower semiconductor build 102 and an upper portion 150-U in the upper semiconductor build 101 and the e-fuse link 150 extends across the joining interface 130. A technical benefit includes an easily manufacturable e-fuse which saves space while providing strong bonding interface for two semiconductor builds.

Optionally, the at least one of the first e-fuse terminal 141 or the second e-fuse terminal 142 includes an upper contact pad 140-U in the upper semiconductor build 101 in contact with a lower contact pad 140-L in the lower semiconductor build 102. A technical benefit includes enabling the e-fuse to be controlled by either semiconductor build.

Optionally, the hybrid bonded semiconductor structure further includes a pad level dielectric layer wherein a total height 181 of the e-fuse link 150 is greater than a height 182 of the pad level dielectric 192. A technical benefit includes enabling a strong bonding of two builds without an excessively large e-fuse link at the bonding (joining) interface.

Optionally, a width 211 of the upper portion of e-fuse link 150-U is less than a width 222 of a lower portion of an e-fuse link. A technical benefit includes ease of manufacture because allows for relaxed alignment rules.

Optionally, the hybrid bonded semiconductor structure of claim 1, further includes a heater 300 adjacent to the fuse link 150. A technical benefit includes enabling aid in blowing fuse with least amount of current/voltage.

Optionally, the e-fuse link is selected from the group consisting of thin metal trace, conductive doped oxides, conductive silicides, or other electrically conductive materials. A technical benefit includes ease of manufacture through use materials that can be readily integrated into the builds.

In another aspect, another exemplary hybrid bonded semiconductor structure 100 includes a lower semiconductor build 102, an upper semiconductor build 101 on the lower semiconductor build, a joining interface 130 where the lower and upper semiconductor builds meet, a first e-fuse terminal 141 in the first semiconductor build, a second e-fuse terminal 142 comprising an upper contact pad 140-U in the upper semiconductor build 101 in contact with a lower contact pad 140-L in the lower semiconductor build 102, and an e-fuse link 150 between the first and second e-fuse terminals. A technical benefit includes providing strong bonding interface while allowing the e-fuse to be controlled by either semiconductor build.

Optionally, the hybrid bonded semiconductor structure further includes a pad level dielectric layer wherein a height 181 of the e-fuse link 150 is less than a height 182 of the pad level dielectric A technical benefit includes providing a smaller e-fuse link which is easier to blow.

Optionally, a top surface of the e-fuse link 150 is covered by the pad dielectric. A technical benefit includes it is less likely the bonding interface will be damaged by the fuse blow.

Optionally, the top surface of the first terminal 141 is coplanar with the pad dielectric. A technical benefit includes ease of manufacture as the same mask and processing can be used for the e-fuse elements and other pad level features.

Optionally, the hybrid bonded semiconductor structure further includes a heater 300 adjacent to the fuse link 150. A technical benefit includes aid in blowing the e-fuse with least amount of current/voltage.

Optionally, the e-fuse link is selected from the group consisting of thin metal trace, conductive doped oxides, conductive silicides, or other electrically conductive materials. A technical benefit includes ease of manufacture through use materials that can be readily integrated into the builds.

In a further aspect, an exemplary hybrid bonded semiconductor structure 100 includes a lower semiconductor build 102, an upper semiconductor build 101 on the lower semiconductor build, a joining interface 130 where the lower and upper semiconductor builds meet, a first e-fuse terminal 141 in the first semiconductor build, a second e-fuse terminal 142 comprising an upper contact pad 140-U in the upper semiconductor build 101 in contact with a lower contact pad 140-L in the lower semiconductor build 102, and an e-fuse link 150 between the first and second e-fuse terminals wherein the top surface of the first terminal 141 is at least partially covered by the e-fuse link 150. A technical benefit includes providing strong bonding interface while allowing the e-fuse to be controlled by either semiconductor build.

Optionally, the hybrid bonded semiconductor structure further includes a pad level dielectric layer wherein a height 181 of the e-fuse link 150 is less than a height 182 of the pad level dielectric. A technical benefit includes providing a smaller e-fuse link which is easier to blow.

Optionally, at least a portion of a top surface of the e-fuse link 150 is covered by the pad dielectric. A technical benefit includes that it is less likely the bonding interface will be damaged by the fuse blow.

Optionally, at least another portion of the top surface of the e-fuse link 150 is covered by the lower contact pad 140-L. A technical benefit is ease of alignment of link and contact pad

Optionally, the hybrid bonded semiconductor structure of claim 13, further includes a heater 300 adjacent the fuse link 150. A technical benefit is aid in blowing the fuse with least amount of current/voltage.

Optionally, the e-fuse link is selected from the group consisting of thin metal trace, conductive doped oxides, conductive silicides, or other electrically conductive materials. A technical benefit is ease of manufacture to use materials that can be readily integrated into the builds.

In a further aspect, an exemplary hybrid bonded semiconductor structure 100 includes a lower semiconductor build 102, an upper semiconductor build 101 on the lower semiconductor build, a joining interface 130 where the lower and upper semiconductor builds meet, a first e-fuse terminal 141, a second e-fuse terminal 142, wherein each e-fuse terminal comprises an upper contact pad 140-U in the upper semiconductor build 101 in contact with a lower contact pad 140-L in the lower semiconductor build 102, and an e-fuse link 150 connecting the first and second e-fuse terminals. A technical benefit includes providing strong bonding interface while allowing the e-fuse to be controlled by either semiconductor build.

Optionally, the top of the e-fuse link 150 contacts the bottom of the lower contact pads 140-L of the first and second terminals. A technical benefit includes ease of integration.

Optionally, the e-fuse link is selected from the group consisting of thin metal trace, conductive doped oxides, conductive silicides, or other electrically conductive materials. A technical benefit includes ease of manufacture to use materials that can be readily integrated into the builds.

In a further aspect, an exemplary hybrid bonded semiconductor structure 100 includes a lower semiconductor build 102, an upper semiconductor build 101 on the lower semiconductor build, a joining interface 130 where the lower and upper semiconductor builds meet, an upper contact pad 140-U in the upper semiconductor build 101 in contact with a lower contact pad 140-L in the lower semiconductor build 102, a vertical e-fuse link 150 at a via level electrically connected to the lower contact pad, and a heater 300 adjacent the vertical e-fuse link. A technical benefit includes providing strong bonding interface while allowing the e-fuse to be controlled by either semiconductor build.

Optionally, the heater laterally surrounds the vertical e-fuse link. A technical benefit is aid in blowing the fuse with least amount of current/voltage.

Optionally, the heater comprises two arms that laterally surrounds the vertical e-fuse link. A technical benefit is providing an e-fuse surrounded by a heater without creating electrical interference.

Optionally, the e-fuse link is selected from the group consisting of thin metal trace, conductive doped oxides, conductive silicides, or other electrically conductive materials. A technical benefit includes ease of manufacture to use materials that can be readily integrated into the builds.

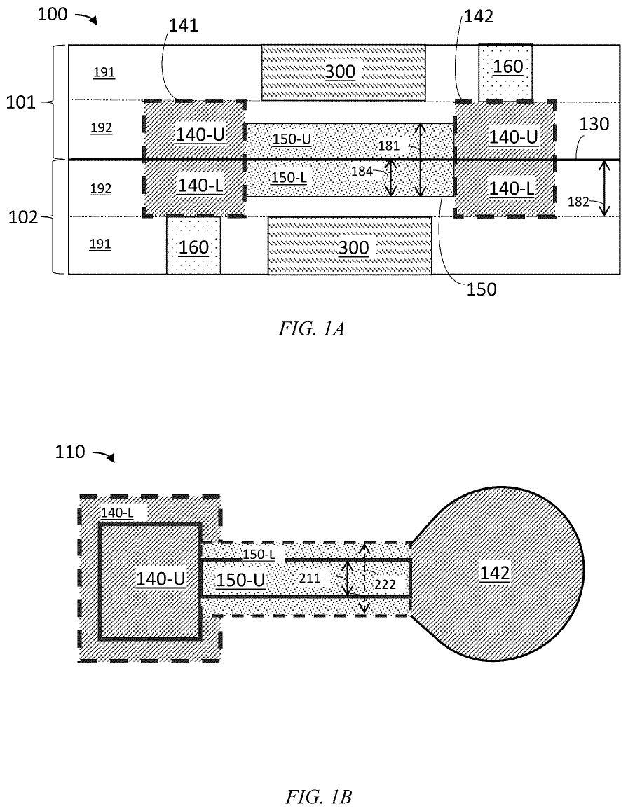

Aspects of invention provide techniques for an e-fuse structure integrated in a hybrid bonded semiconductor structure 100 which allows programming from one semiconductor build to another. Referring to FIG. 1A which shows a cross-section of an embodiment of a hybrid bond semiconductor structure 100 which includes a lower build semiconductor build 102 having a surface with metal and dielectric portions and an upper semiconductor build 101 having a surface with metal and dielectric portions connected by a hybrid bond joining interface 130. A “semiconductor build” can be a wafer or a die; thus, the hybrid bonded semiconductor builds can be wafer to wafer, die to die or wafer to die. The semiconductor build surfaces are put in contact and heat is applied to bond the semiconductor builds together. In hybrid bonding, the dielectric portions of the lower and upper semiconductor builds bond to each other while at the same time metal portions of the lower and upper semiconductor builds bond to each other. The metal-to-metal bonding can include lower contact bonding pads 140-L and upper contact bonding pads 140-U which meet to form bonded contact pairs. The contact bonding pads can be copper or other suitable conductor. The contact bonding pads are embedded in a pad level dielectric 192. Pad level dielectric 192 can include multiple layers of one of more dielectric layers, for example, silicon dioxide, silicon nitride, SiON, SiOCN, SiOC, or other suitable dielectric.

In FIG. 1A, an e-fuse structure includes a first e-fuse terminal 141 and a second e-fuse terminal 142 connected by an e-fuse link 150. The bonded contact pairs of the lower and upper contact bonding pads make up the first e-fuse terminal 141 and a second e-fuse terminal 142, thus the terminals exist in both semiconductor builds and span the joining interface 130. Similarly, in the FIG. 1A embodiment, the e-fuse link 150 has a lower portion 150-L and an upper portion 150-U in the lower semiconductor build 102 and upper semiconductor build 101, respectively. The lower portion 150-L and an upper portion 150-U are bonded together such that the e-fuse link 150 also spans the joining interface 130. Therefore, the total height 181 of the e-fuse link 150 can be greater than the height 182 of the pad dielectric 192 while each portion (i.e. lower portion 150-L and upper portion 150-U) of the e-fuse link may have a portion height 194 which is less than the height 182 of the pad dielectric 192. The e-fuse link 150 material can be a thin metal trace, conductive doped oxides, conductive silicides, or other electrically conductive materials. In both semiconductor builds, under the e-fuse structure, an interlevel dielectric layer 191 may include metallizations 160 providing electrical connection to the e-fuse terminals. The interlevel dielectric layer 191 may have embedded resistive heater 300 elements located adjacent to the e-fuse link 150. Activation of the heater 300 can enhance electromigration in the e-fuse link 150 to aid in programming the e-fuse.

Refer now to FIG. 1B, which shows a top-down illustration, by way of example and not by limitation, of various possible configurations of the e-fuse structure 110 of FIG. 1A. On the right hand side, an e-fuse terminal having a lower contact bonding pads 140-L and an upper contact bonding pads 140-U of different sizes is shown. Likewise the e-fuse link's lower portion 105-L may have a width 122 greater than the width 211 of the upper portion 150-U. Because the widths of the e-fuse links can be small (for example, from about 0.10 μm to about 1 μm), having a portion of the e-fuse link in one semiconductor build larger than the e-fuse link on the other semiconductor build can ensure bonding of the lower and upper portions of the e-fuse link even with less than perfect alignment. Referring to the left hand side, a second e-fuse terminal 142 illustrates alternative shapes available, here a contact pad which tapers toward the e-fuse link. It is not necessary that the configurations have different sizes or shapes, in fact, matching sizes and shapes can also be used.

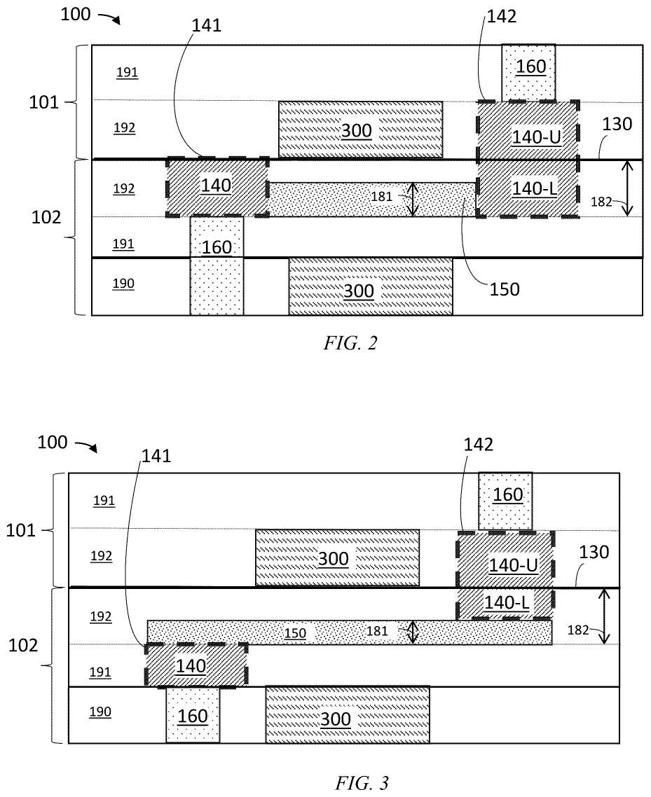

Referring to FIG. 2 which shows a cross-section of another embodiment of a hybrid bond semiconductor structure 100 which includes a lower build semiconductor build 102 having a surface with metal and dielectric portions and an upper semiconductor build 101 having a surface with metal and dielectric portions connected by a hybrid bond joining interface 130. In FIG. 2, an e-fuse structure includes a first e-fuse terminal 141 and a second e-fuse terminal 142 connected by an e-fuse link 150. The first e-fuse terminal 141 is a non-bonded contact pad 140 embedded in and co-planar with pad dielectric 192 of the lower semiconductor build 102. A bonded contact pair of the lower contact bonding pad 140-L and upper contact bonding pad 140-U make up the second e-fuse terminal 142, thus the second e-fuse terminal 142 exists in both semiconductor builds and span the joining interface 130. The e-fuse link 150 is in the lower semiconductor build 102 and it's top surface is covered by pad dielectric 192. Therefore, in FIG. 2, the total height 181 of the e-fuse link 150 of FIG. 2 can be less than the height 182 of the pad dielectric 192. The e-fuse link 150 material can be a thin metal trace, conductive doped oxides, conductive silicides, or other electrically conductive materials. In both semiconductor builds, under the e-fuse structure, an interlevel dielectric layer 191 may include metallizations 160 providing electrical connection to the e-fuse terminals. The interlevel dielectric layer 191 or pad dielectric 192 of each semiconductor build can have embedded resistive heater 300 elements located adjacent to the e-fuse link 150. Activation of the heater 300 can enhance electromigration in the e-fuse link 150 to aid in programming the e-fuse.

Referring to FIG. 3 which shows a cross-section of yet another embodiment of a hybrid bond semiconductor structure 100 which includes a lower semiconductor build 102 having a surface with metal and dielectric portions and an upper semiconductor build 101 having a surface with metal and dielectric portions connected by a hybrid bond joining interface 130. In FIG. 3, an e-fuse structure includes a first e-fuse terminal 141 and a second e-fuse terminal 142 connected by an e-fuse link 150. The first e-fuse terminal 141 is a non-bonded contact pad 140 embedded in and co-planar with interlayer dielectric 191 of the lower semiconductor build 102. A bonded contact pair of the lower contact bonding pad 140-L and upper contact bonding pad 140-U make up the second e-fuse terminal 142; thus, the second e-fuse terminal 142 exists in both semiconductor builds and span the joining interface 130. The e-fuse link 150 is in the lower semiconductor build 102 and its top surface is covered by pad dielectric 192. In FIG. 3, e-fuse link 150 covers a top surface of the first e-fuse terminal 141 and the second e-fuse terminal 142 can land on a top surface of the e-fuse link 150. Therefore, in FIG. 3, the total height 181 of the e-fuse link 150 of FIG. 3 can be less than the height 182 of the pad dielectric 192. The e-fuse link 150 material can be thin metal trace, conductive doped oxides, conductive silicides, or other electrically conductive materials. In both semiconductor builds, under the e-fuse structure, an interlevel dielectric layer 191 or additional dielectric layers 190 may include metallizations 160 providing electrical connection to the e-fuse terminals. The additional dielectric layer 190 or pad dielectric 192 of each semiconductor build can have embedded resistive heater 300 elements located adjacent to the e-fuse link 150. Activation of the heater 300 can enhance electromigration in the e-fuse link 150 to aid in programming the e-fuse.

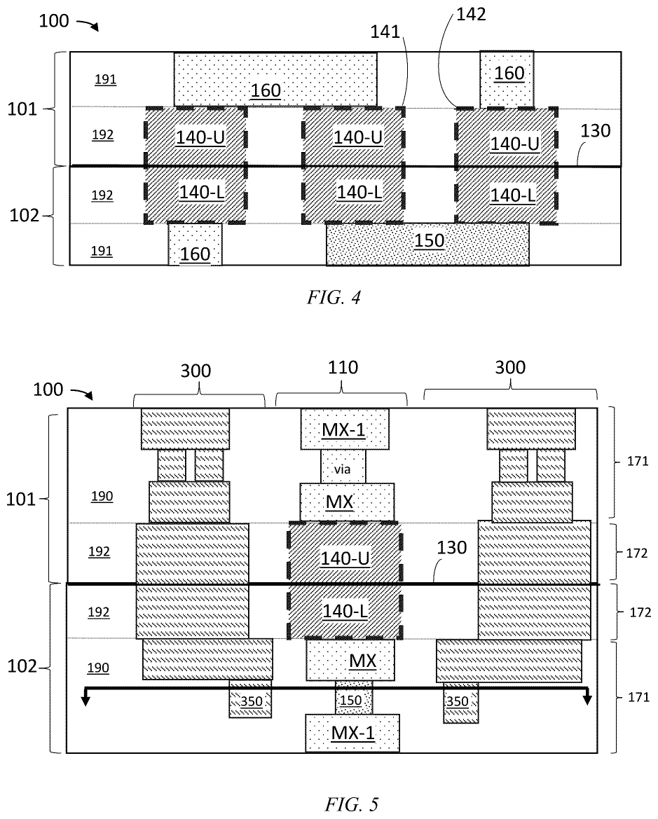

Referring to FIG. 4 which shows a cross-section of a further embodiment of a hybrid bond semiconductor structure 100 which includes a lower build semiconductor build 102 having a surface with metal and dielectric portions and an upper semiconductor build 101 having a surface with metal and dielectric portions connected by a hybrid bond joining interface 130. The metal-to-metal bonding can include lower contact bonding pads 140-L and upper contact bonding pads 140-U which meet to form bonded contact pairs. The contact bonding pads can be copper or other suitable conductor. The contact bonding pads are embedded in a pad level dielectric 192. Pad level dielectric 192 can include multiple layers of one of more dielectric layers, for example, silicon dioxide, silicon nitride, SiON, SiOCN, SiOC, or other suitable dielectric. In FIG. 4, an e-fuse structure includes a first e-fuse terminal 141 and a second e-fuse terminal 142 connected by an e-fuse link 150. The bonded contact pairs of the lower and upper contact bonding pads make up the first e-fuse terminal 141 and a second e-fuse terminal 142; thus, the terminals exist in both semiconductor builds and span the joining interface 130. In the FIG. 4 embodiment, the e-fuse link 150 is embedded and coplanar with an interlevel dielectric 191 in the lower semiconductor build 102. The first and second e-fuse terminals land on the e-fuse link 150. The e-fuse link 150 material can be thin metal trace, conductive doped oxides, conductive silicides, or other electrically conductive materials. In both semiconductor builds, under the e-fuse structure, an interlevel dielectric layer 191 can include metallizations 160 providing electrical connection to the e-fuse terminals.

Referring to FIG. 5 which shows a cross-section of an embodiment of a hybrid bond semiconductor structure 100 which includes a lower semiconductor build 102 having a surface with metal and dielectric portions and an upper semiconductor build 101 having a surface with metal and dielectric portions connected by a hybrid bond joining interface 130. The metal-to-metal bonding can include lower contact bonding pads 140-L and upper contact bonding pads 140-U which meet to form bonded contact pairs. The contact bonding pads can be copper or other suitable conductor. The contact bonding pads are embedded in a pad level dielectric 192. Pad level dielectric 192 can include multiple layers of one of more dielectric layers, for example, silicon dioxide, silicon nitride, SiON, SiOCN, SiOC, or other suitable dielectric. In FIG. 5, the bonded contact pairs of the lower and upper contact bonding pads span the joining interface 130 to connect the lower and upper semiconductor builds. The e-fuse link 150 is in an additional dielectric layer 190 (advantageously at a via level as opposed to a metal (M) level) in of the lower semiconductor build 102. The e-fuse link 150 material can be thin metal trace, conductive doped oxides, conductive silicides, or other electrically conductive materials. On either side of the e-fuse structure 110 there can be embedded resistive heater 300 elements located adjacent to the e-fuse link 150. Advantageously, a portion 350 of the heater laterally surrounds the e-fuse link 150. Activation of the heater 300 can enhance electromigration in the e-fuse link 150 to aid in programming the e-fuse.

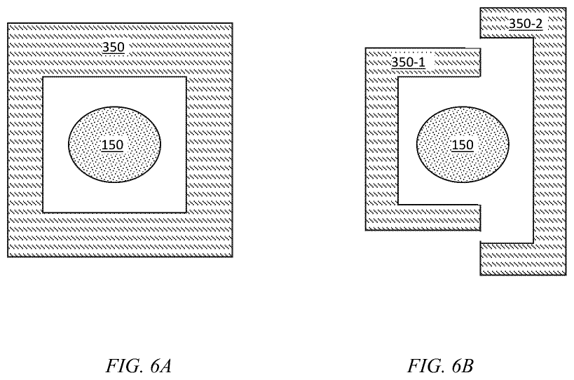

The arrows of FIG. 5 indicate the location of a top-down view of e-fuse link 150 and heater portions 350 FIGS. 6A and 6B. FIG. 6A show a configuration of the portion 350 of the heater 300 which laterally surrounds the e-fuse link 150 in a continuous manner. Advantageously, the configuration of FIG. 6A allows for uniform, close spacing around the e-fuse link to aid in programming. However, circular structures sometimes interfere with electronics and therefore a discontinuous lateral surrounding of the e-fuse link 150 shown in FIG. 6B can alternatively be used.

With reference to FIGS. 2 through 5, an e-fuse link 150 is shown only in lower semiconductor build 102. It should be noted that in each case, upper semiconductor build 101 may also have an e-fuse such that two e-fuse links 150 exist, one in each build. The upper semiconductor build 101 may be a mirror image of the lower semiconductor build 102, or a mirror image flipped left to right or any combination of e-fuse link 150 in both builds. Accordingly, one or more embodiments of the invention have individual e-fuse elements of the final structure located on different semiconductor builds. Consequently, the structure can spans the interface between two different semiconductor builds. One or more embodiments, therefore, can connect and bridge two individual builds and can be used as a gate or pass that can limit the electrical signals passing from one build to its adjoined build. Thus providing a security feature or electrical surge protection.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A hybrid bonded semiconductor structure 100 comprising:
a lower semiconductor build;
an upper semiconductor build on the lower semiconductor build;
a joining interface where the lower and upper semiconductor builds meet;
a first e-fuse terminal at least partially in the lower semiconductor build;
a second e-fuse terminal at least partially in the upper semiconductor build;
an e-fuse link between the first and second e-fuse terminals;
wherein the e-fuse link comprises a lower portion in the lower semiconductor build and an upper portion in the upper semiconductor build and the e-fuse link extends across the joining interface.

2. The hybrid bonded semiconductor structure of claim 1, wherein at least one of the first e-fuse terminal or the second e-fuse terminal comprises an upper contact pad in the upper semiconductor build in contact with a lower contact pad in the lower semiconductor build.

3. The hybrid bonded semiconductor structure of claim 1, further comprising a pad level dielectric layer wherein a total height of the e-fuse link is greater than a height of the pad level dielectric.

4. The hybrid bonded semiconductor structure of claim 1, wherein a width of the upper portion of e-fuse link is less than a width of a lower portion of an e-fuse link.

5. The hybrid bonded semiconductor structure of claim 1, further comprising a heater adjacent to the fuse link.

6. The hybrid bonded semiconductor structure of claim 1, wherein the e-fuse link is selected from the group consisting of thin metal trace, conductive doped oxides, conductive silicides, or other electrically conductive materials.

7. A hybrid bonded semiconductor structure comprising:
a lower semiconductor build;
an upper semiconductor build on the lower semiconductor build;
a joining interface where the lower and upper semiconductor builds meet;
a first e-fuse terminal in the first semiconductor build;
a second e-fuse terminal comprising an upper contact pad in the upper semiconductor build in contact with a lower contact pad in the lower semiconductor build; and
an e-fuse link between the first and second e-fuse terminals.

8. The hybrid bonded semiconductor structure of claim 7, further comprising a pad level dielectric layer wherein a height of the e-fuse link is less than a height of the pad level dielectric.

9. The hybrid bonded semiconductor structure of claim 8, wherein a top surface of the e-fuse link is covered by the pad dielectric.

10. The hybrid bonded semiconductor structure of claim 8, wherein the top surface of the first terminal is coplanar with the pad dielectric.

11. The hybrid bonded semiconductor structure of claim 7, further comprising a heater adjacent to the fuse link.

12. The hybrid bonded semiconductor structure of claim 7, wherein the e-fuse link is selected from the group consisting of thin metal trace, conductive doped oxides, conductive silicides, or other electrically conductive materials.

13. A hybrid bonded semiconductor structure comprising:
a lower semiconductor build;
an upper semiconductor build on the lower semiconductor build;
a joining interface where the lower and upper semiconductor builds meet;
a first e-fuse terminal in the first semiconductor build;
a second e-fuse terminal comprising an upper contact pad in the upper semiconductor build in contact with a lower contact pad in the lower semiconductor build; and
an e-fuse link between the first and second e-fuse terminals;
wherein the top surface of the first terminal is at least partially covered by the e-fuse link.

14. The hybrid bonded semiconductor structure of claim 13, further comprising a pad level dielectric layer wherein a height of the e-fuse link is less than a height of the pad level dielectric.

15. The hybrid bonded semiconductor structure of claim 14, wherein at least a portion of a top surface of the e-fuse link is covered by the pad dielectric.

16. The hybrid bonded semiconductor structure of claim 13, wherein at least another portion of the top surface of the e-fuse link is covered by the lower contact pad.

17. The hybrid bonded semiconductor structure of claim 13, further comprising a heater adjacent to the fuse link.

18. The hybrid bonded semiconductor structure of claim 13, wherein the e-fuse link is selected from the group consisting of thin metal trace, conductive doped oxides, conductive silicides, or other electrically conductive materials.

19. A hybrid bonded semiconductor structure comprising:
a lower semiconductor build;
an upper semiconductor build on the lower semiconductor build;
a joining interface where the lower and upper semiconductor builds meet;
a first e-fuse terminal;
a second e-fuse terminal;
wherein each e-fuse terminal comprises an upper contact pad in the upper semiconductor build in contact with a lower contact pad in the lower semiconductor build; and
an e-fuse link connecting the first and second e-fuse terminals.

20. The hybrid bonded semiconductor structure of claim 19, wherein the top of the e-fuse link contacts the bottom of the lower contact pads of the first and second terminals.

21. The hybrid bonded semiconductor structure of claim 19, wherein the e-fuse link is selected from the group consisting of thin metal trace, conductive doped oxides, conductive silicides, or other electrically conductive materials.

22. A hybrid bonded semiconductor structure comprising:
a lower semiconductor build;
an upper semiconductor build on the lower semiconductor build;
a joining interface where the lower and upper semiconductor builds meet;
an upper contact pad in the upper semiconductor build in contact with a lower contact pad in the lower semiconductor build;
a vertical e-fuse link at a via level electrically connected to the lower contact pad; and
a heater adjacent to the vertical e-fuse link.

23. The hybrid bonded semiconductor structure of claim 22 wherein the heater laterally surrounds the vertical e-fuse link.

24. The hybrid bonded semiconductor structure of claim 22 wherein the heater comprises two arms that laterally surround the vertical e-fuse link.

25. The hybrid bonded semiconductor structure of claim 22, wherein the e-fuse link is selected from the group consisting of thin metal trace, conductive doped oxides, conductive silicides, or other electrically conductive materials.
